(19) United States
(12) Patent Application Publication
(10) Pub. No.: US 2022/0121397 A1
(43) Pub. Date: Apr. 21, 2022

(54) Internal Compression Storage Devices

(71) Applicant: Western Digital Technologies, Inc., San Jose, CA (US)

(72) Inventor: Divya Appaji Lalithamba, Bangalore (IN)

(21) Appl. No.: 17/181,805

(22) Filed: Feb. 22, 2021

Related U.S. Application Data
(60) Provisional application No. 63/093,007, filed on Oct. 16, 2020.

(51) Int. Cl. G06F 3/06; G06F 11/10; H03M 7/48

(52) U.S. Cl. CPC G06F 3/0659; G06F 11/1076; H03M 7/48; G06F 3/0673; G06F 3/0608

(57) ABSTRACT

A storage device utilizing internal compression codecs may reduce the overall amount of data required for storage within the memory devices, increasing storage device life spans and available storage space. Data provided to the storage device is compressed prior to storage and decompressed upon retrieval. The data may be formatted at a fixed length to streamline compression processing. The processing time of the compression codecs may be minimized through the use of hardware-based resources when needed. These compression codec storage devices may include one or more communication channels suitable for connection with a host, memory devices within a memory array, and controllers configured to transfer host data from the host-computing device to the memory array. Internal compression codecs can be configured to retrieve host data from one or more buffers, compress the host data with a fixed-input compression method, and store the compressed data within one or more memory devices.

### PRIORITY

This application claims the benefit of and priority to U.S. Provisional Application No. 63/093,007, filed Oct. 16, 2021, which is incorporated in its entirety herein.

### FIELD

The present disclosure relates to storage systems. More particularly, the present disclosure relates to utilizing one or more compression codecs within the backend of a storage device.

### BACKGROUND

Storage devices are ubiquitous within computing systems. Recently, solid-state memory devices capable of nonvolatile storage have become the predominant choice within various consumer electronics products. These storage devices can communicate and utilize various protocols including non-volatile memory express (NVMe), and peripheral component interconnect express (PCIe) to reduce processing overhead and increase efficiency.

One of the limiting factors of solid-state drives (SSDs) is that each memory device within the SSD has a finite endurance. Each time data is written to a memory device within an SSD, the ability to properly store that data slightly decreases. The number of write cycles that can be performed on the memory device before failure is expressed as the endurance of that memory device. The type of memory device utilized within the storage device can directly affect the endurance of that SSD as increased density memory devices typically provide fewer write cycles before failure compared to lower density memory devices.

A measure for describing how many cumulative writes a storage device can reasonably expect to complete over its lifespan is called Terabytes Written (TBW). Increasing the overall storage capacity of a drive may also directly affect the TBW as the amount of space in which to write increases. Storage device manufacturers typically attempt to increase size of available storage on the devices while providing an acceptable TBW rating for the storage device. However, when a storage device is nearly at full capacity, increased levels of write cycles may be utilized by the operating system and/or storage device controller to shuffle data around to make more memory devices available for storage.

### BRIEF DESCRIPTION OF DRAWINGS

The above, and other, aspects, features, and advantages of several embodiments of the present disclosure will be more apparent from the following description as presented in conjunction with the following several figures of the drawings.

FIG. 1 is a schematic block diagram of a host-computing device with a storage device suitable for internal compression codecs in accordance with an embodiment of the disclosure;

FIG. 2 is a schematic block diagram of a storage device suitable for utilizing internal compression codecs in accordance with an embodiment of the disclosure;

FIG. 3 is a conceptual illustration of a storage device backend utilizing an internal compression codec in accordance with an embodiment of the disclosure;

FIG. 4 is a table depicting a sample of compression encodings in accordance with embodiments of the disclosure;

FIG. 5 is a conceptual illustration of a cascading compression process in accordance with an embodiment of the disclosure;

FIG. 6A is a flowchart depicting a process for utilizing internal compression when storing data to a plurality of memory devices in accordance with embodiments of the disclosure;

FIG. 6B is a flowchart depicting a process for utilizing internal compression when retrieving data from a plurality of memory devices in accordance with embodiments of the disclosure; and

FIG. 7 is a flowchart depicting a process for generating additional storage space within a storage device utilizing one or more cascading compression processes in accordance with embodiments of the disclosure.

Corresponding reference characters indicate corresponding components throughout the several figures of the drawings. Elements in the several figures are illustrated for simplicity and clarity and have not necessarily been drawn to scale. For example, the dimensions of some of the elements in the figures might be emphasized relative to other elements for facilitating understanding of the various presently disclosed embodiments. In addition, common, but well-understood, elements that are useful or necessary in a commercially feasible embodiment are often not depicted in order to facilitate a less obstructed view of these various embodiments of the present disclosure.

### DETAILED DESCRIPTION

In response to the problems described above, devices, systems, and methods are discussed herein that describe utilizing one or more internal compression codecs within the storage device. There is a need to reduce the number of bits that are written to memory devices within a storage device, and there is a need to increase the overall storage capacity to improve various metrics such as a storage device's TBW. As will be described in more detail below, increases in storage capacity efficiency and a reduction in the overall number of write cycles required may be realized by utilizing an internal compression codec.

Embodiments described herein can increase the storage capacity and endurance of a storage device without any physical blocks or memory devices (cells) being added to the memory array. A compression codec (i.e., (en)coder/decoder) can be placed within the data write and read signal paths and configured to compress all incoming data and decompress all outgoing data. This compression codec may be realized through software, hardware, or various combinations as needed. In some embodiments, multiple codecs may be available and utilized based on the desired application or current processing needs.

In further embodiments, the compression codec may provide the ability to recompress previously compressed data to further increase the efficiency of the storage device. As described below, data may be recompressed (i.e., cascaded) through multiple levels until an input requirement is not met. In a variety of embodiments, the input requirement can be a fixed input which requires a particular number of bits to process and compress/recompress. The recompression process will stop when the data cannot satisfy that fixed input (e.g., having fewer bits than necessary).

The compression codec may be configured to receive and process all data placed within a buffer and then pass the compressed/recompressed data to an error correction codec that may further process and/or add parity bits to the data prior to storage within one or more memory devices. Upon request for data retrieval, the stored data is verified by the error correction codec before being decompressed (i.e., decoded) by the compression codec before being sent back to the buffer. In certain embodiments, the storage device may activate and compress/recompress the data stored within the memory devices in response to a low storage space signal.

The amount of compression, recompression, and decompression may be regulated by one or more thresholds including time-based thresholds. Various embodiments may determine if particular thresholds have been exceeded during operations which may activate additional hardware and/or software resources to decrease the overall processing time. This may be done to bring the data write and read processes within a pre-determined specification. In additional embodiments, the thresholds may be configured dynamically to keep the overall read and write performance of the storage device within one or more specifications provided to customers prior to purchase.

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “function,” “module,” “apparatus,” or “system.” Furthermore, aspects of the present disclosure may take the form of a computer program product embodied in one or more non-transitory computer-readable storage media storing computer-readable and/or executable program code. Many of the functional units described in this specification have been labeled as functions, in order to emphasize their implementation independence more particularly. For example, a function may be implemented as a hardware circuit comprising custom VLSI circuits or gate arrays, off-the-shelf semiconductors such as logic chips, transistors, or other discrete components. A function may also be implemented in programmable hardware devices such as via field programmable gate arrays, programmable array logic, programmable logic devices, or the like.

Functions may also be implemented at least partially in software for execution by various types of processors. An identified function of executable code may, for instance, comprise one or more physical or logical blocks of computer instructions that may, for instance, be organized as an object, procedure, or function. Nevertheless, the executables of an identified function need not be physically located together but may comprise disparate instructions stored in different locations which, when joined logically together, comprise the function and achieve the stated purpose for the function.

Indeed, a function of executable code may include a single instruction, or many instructions, and may even be distributed over several different code segments, among different programs, across several storage devices, or the like. Where a function or portions of a function are implemented in software, the software portions may be stored on one or more computer-readable and/or executable storage media. Any combination of one or more computer-readable storage media may be utilized. A computer-readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object-oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the functions and/or modules described herein, in certain embodiments, may alternatively be embodied by or implemented as a component.

A circuit, as used herein, comprises a set of one or more electrical and/or electronic components providing one or more pathways for electrical current. In certain embodiments, a circuit may include a return pathway for electrical current, so that the circuit is a closed loop. In another embodiment, however, a set of components that does not include a return pathway for electrical current may be referred to as a circuit (e.g., an open loop). For example, an integrated circuit may be referred to as a circuit regardless of whether the integrated circuit is coupled to ground (as a return pathway for electrical current) or not. In various embodiments, a circuit may include a portion of an integrated circuit, an integrated circuit, a set of integrated circuits, a set of non-integrated electrical and/or electrical components with or without integrated circuit devices, or the like. In one embodiment, a circuit may include custom VLSI circuits, gate arrays, logic circuits, or other integrated circuits; off-the-shelf semiconductors such as logic chips, transistors, or other discrete devices; and/or other mechanical or electrical devices. A circuit may also be implemented as a synthesized circuit in a programmable hardware device such as field programmable gate array, programmable array logic, programmable logic device, or the like (e.g., as firmware, a netlist, or the like). A circuit may comprise one or more silicon integrated circuit devices (e.g., chips, die, die planes, packages) or other discrete electrical devices, in electrical communication with one or more other components through electrical lines of a printed circuit board (PCB) or the like. Each of the functions and/or modules described herein, in certain embodiments, may be embodied by or implemented as a circuit.

Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to”, unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Further, as used herein, reference to reading, writing, storing, buffering, and/or transferring data can include the entirety of the data, a portion of the data, a set of the data, and/or a subset of the data. Likewise, reference to reading, writing, storing, buffering, and/or transferring non-host data can include the entirety of the non-host data, a portion of the non-host data, a set of the non-host data, and/or a subset of the non-host data.

Lastly, the terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps, or acts are in some way inherently mutually exclusive.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

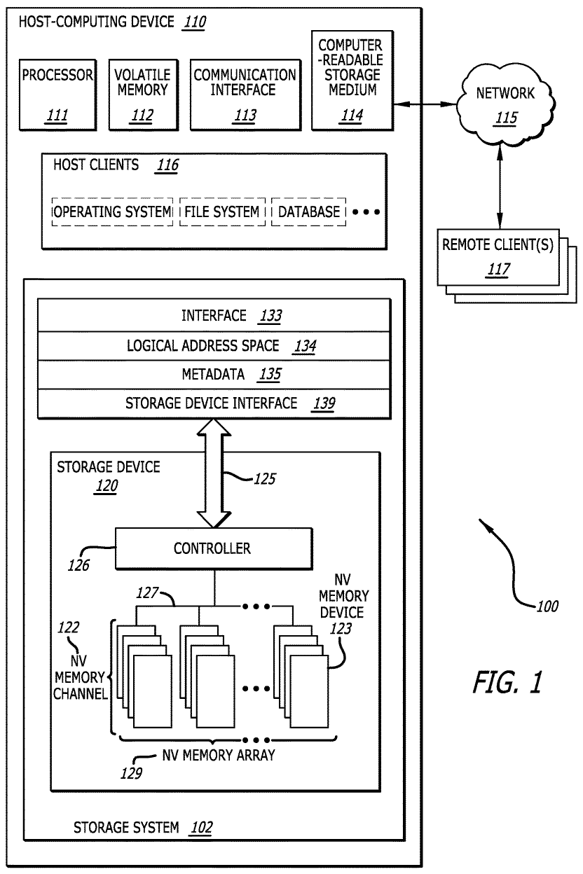

Referring to FIG. 1, a schematic block diagram of a host-computing device 110 with a storage device 120 suitable for internal compression codecs in accordance with an embodiment of the disclosure is shown. The internal data compression system 100 comprises one or more storage devices 120 of a storage system 102 within a host-computing device 110 in communication via a controller 126. The host-computing device 110 may include a processor 111, volatile memory 112, and a communication interface 113. The processor 111 may include one or more central processing units, one or more general-purpose processors, one or more application-specific processors, one or more virtual processors (e.g., the host-computing device 110 may be a virtual machine operating within a host), one or more processor cores, or the like. The communication interface 113 may include one or more network interfaces configured to communicatively couple the host-computing device 110 and/or controller 126 of the storage device 120 to a communication network 115, such as an Internet Protocol (IP) network, a Storage Area Network (SAN), wireless network, wired network, or the like.

The storage device 120, in various embodiments, may be disposed in one or more different locations relative to the host-computing device 110. In one embodiment, the storage device 120 comprises one or more non-volatile memory devices 123, such as semiconductor chips or packages or other integrated circuit devices disposed on one or more printed circuit boards, storage housings, and/or other mechanical and/or electrical support structures. For example, the storage device 120 may comprise one or more direct inline memory module (DIMM) cards, one or more expansion cards and/or daughter cards, a solid-state-drive (SSD) or other hard drive device, and/or may have another memory and/or storage form factor. The storage device 120 may be integrated with and/or mounted on a motherboard of the host-computing device 110, installed in a port and/or slot of the host-computing device 110, installed on a different host-computing device 110 and/or a dedicated storage appliance on the network 115, in communication with the host-computing device 110 over an external bus (e.g., an external hard drive), or the like.

The storage device 120, in one embodiment, may be disposed on a memory bus of a processor 111 (e.g., on the same memory bus as the volatile memory 112, on a different memory bus from the volatile memory 112, in place of the volatile memory 112, or the like). In a further embodiment, the storage device 120 may be disposed on a peripheral bus of the host-computing device 110, such as a peripheral component interconnect express (PCI Express or PCIe) bus such, as but not limited to a NVM Express (NVMe) interface, a serial Advanced Technology Attachment (SATA) bus, a parallel Advanced Technology Attachment (PATA) bus, a small computer system interface (SCSI) bus, a FireWire bus, a Fibre Channel connection, a Universal Serial Bus (USB), a PCIe Advanced Switching (PCIe-AS) bus, or the like. In another embodiment, the storage device 120 may be disposed on a communication network 115, such as an Ethernet network, an Infiniband network, SCSI RDMA over a network 115, a storage area network (SAN), a local area network (LAN), a wide area network (WAN) such as the Internet, another wired and/or wireless network 115, or the like.

The host-computing device 110 may further comprise a computer-readable storage medium 114. The computer-readable storage medium 114 may comprise executable instructions configured to cause the host-computing device 110 (e.g., processor 111) to perform steps of one or more of the methods disclosed herein. Additionally, or in the alternative, the buffering component 150 may be embodied as one or more computer-readable instructions stored on the computer-readable storage medium 114.

A device driver and/or the controller 126, in certain embodiments, may present a logical address space 134 to the host clients 116. As used herein, a logical address space 134 refers to a logical representation of memory resources. The logical address space 134 may comprise a plurality (e.g., range) of logical addresses. As used herein, a logical address refers to any identifier for referencing a memory resource (e.g., data), including, but not limited to: a logical block address (LBA), cylinder/head/sector (CHS) address, a file name, an object identifier, an inode, a Universally Unique Identifier (UUID), a Globally Unique Identifier (GUID), a hash code, a signature, an index entry, a range, an extent, or the like.

A device driver for the storage device 120 may maintain metadata 135, such as a logical to physical address mapping structure, to map logical addresses of the logical address space 134 to media storage locations on the storage device(s) 120. A device driver may be configured to provide storage services to one or more host clients 116. The host clients 116 may include local clients operating on the host-computing device 110 and/or remote clients 117 accessible via the network 115 and/or communication interface 113. The host clients 116 may include, but are not limited to: operating systems, file systems, database applications, server applications, kernel-level processes, user-level processes, applications, and the like.

In many embodiments, the host-computing device 110 can include a plurality of virtual machines which may be instantiated or otherwise created based on user-request. As will be understood by those skilled in the art, a host-computing device 110 may create a plurality of virtual machines configured as virtual hosts which is limited only on the available computing resources and/or demand. A hypervisor can be available to create, run, and otherwise manage the plurality of virtual machines. Each virtual machine may include a plurality of virtual host clients similar to host clients 116 that may utilize the storage system 102 to store and access data.

The device driver may be further communicatively coupled to one or more storage systems 102 which may include different types and configurations of storage devices 120 including, but not limited to: solid-state storage devices, semiconductor storage devices, SAN storage resources, or the like. The one or more storage devices 120 may comprise one or more respective controllers 126 and non-volatile memory channels 122. The device driver may provide access to the one or more storage devices 120 via any compatible protocols or interface 133 such as, but not limited to, SATA and PCIe. The metadata 135 may be used to manage and/or track data operations performed through the protocols or interfaces 133. The logical address space 134 may comprise a plurality of logical addresses, each corresponding to respective media locations of the one or more storage devices 120. The device driver may maintain metadata 135 comprising any-to-any mappings between logical addresses and media locations.

A device driver may further comprise and/or be in communication with a storage device interface 139 configured to transfer data, commands, and/or queries to the one or more storage devices 120 over a bus 125, which may include, but is not limited to: a memory bus of a processor 111, a peripheral component interconnect express (PCI Express or PCIe) bus, a serial Advanced Technology Attachment (ATA) bus, a parallel ATA bus, a small computer system interface (SCSI), FireWire, Fibre Channel, a Universal Serial Bus (USB), a PCIe Advanced Switching (PCIe-AS) bus, a network 115, Infiniband, SCSI RDMA, or the like. The storage device interface 139 may communicate with the one or more storage devices 120 using input-output control (IO-CTL) command(s), IO-CTL command extension(s), remote direct memory access, or the like.

The communication interface 113 may comprise one or more network interfaces configured to communicatively couple the host-computing device 110 and/or the controller 126 to a network 115 and/or to one or more remote clients 117 (which can act as another host). The controller 126 is part of and/or in communication with one or more storage devices 120. Although FIG. 1 depicts a single storage device 120, the disclosure is not limited in this regard and could be adapted to incorporate any number of storage devices 120.

The storage device 120 may comprise one or more non-volatile memory devices 123 of non-volatile memory channels 122, which may include but is not limited to: ReRAM, Memristor memory, programmable metallization cell memory, phase-change memory (PCM, PCME, PRAM, PCRAM, ovonic unified memory, chalcogenide RAM, or C-RAM), NAND flash memory (e.g., 2D NAND flash memory, 3D NAND flash memory), NOR flash memory, nano random access memory (nano RAM or NRAM), nanocrystal wire-based memory, silicon-oxide based sub-10 nanometer process memory, graphene memory, Silicon Oxide-Nitride-Oxide-Silicon (SONOS), programmable metallization cell (PMC), conductive-bridging RAM (CBRAM), magneto-resistive RAM (MRAM), magnetic storage media (e.g., hard disk, tape), optical storage media, or the like. The one or more non-volatile memory devices 123 of the non-volatile memory channels 122, in certain embodiments, comprise storage class memory (SCM) (e.g., write in place memory, or the like).

While the non-volatile memory channels 122 may be referred to herein as “memory media,” in various embodiments, the non-volatile memory channels 122 may more generally comprise one or more non-volatile recording media capable of recording data, which may be referred to as a non-volatile memory medium, a non-volatile memory device, etc. Further, the storage device 120, in various embodiments, may comprise a non-volatile recording device, a non-volatile memory array 129, a plurality of interconnected storage devices in an array, or the like.

The non-volatile memory channels 122 may comprise one or more non-volatile memory devices 123, which may include, but are not limited to: chips, packages, planes, die, etc. A controller 126 may be configured to manage data operations on the non-volatile memory channels 122, and may comprise one or more processors, programmable processors (e.g., FPGAs), ASICs, micro-controllers, or the like. In some embodiments, the controller 126 is configured to store data on and/or read data from the non-volatile memory channels 122, to transfer data to/from the storage device 120, and so on.

The controller 126 may be communicatively coupled to the non-volatile memory channels 122 by way of a bus 127. The bus 127 may comprise an I/O bus for communicating data to/from the non-volatile memory devices 123. The bus 127 may further comprise a control bus for communicating addressing and other command and control information to the non-volatile memory devices 123. In some embodiments, the bus 127 may communicatively couple the non-volatile memory devices 123 to the controller 126 in parallel. This parallel access may allow the non-volatile memory devices 123 to be managed as a group, forming a non-volatile memory array 129. The non-volatile memory devices 123 may be partitioned into respective logical memory units (e.g., logical pages) and/or logical memory divisions (e.g., logical blocks). The logical memory units may be formed by logically combining physical memory units of each of the non-volatile memory devices 123.

The controller 126 may organize a block of word lines within a non-volatile memory device 123, in certain embodiments, using addresses of the word lines, such that the word lines are logically organized into a monotonically increasing sequence (e.g., decoding and/or translating addresses for word lines into a monotonically increasing sequence, or the like). In a further embodiment, word lines of a block within a non-volatile memory device 123 may be physically arranged in a monotonically increasing sequence of word line addresses, with consecutively addressed word lines also being physically adjacent (e.g., WL0, WL1, WL2, . . . WLN).

The controller 126 may comprise and/or be in communication with a device driver executing on the host-computing device 110. A device driver may provide storage services to the host clients 116 via one or more interfaces 133. A device driver may further comprise a storage device interface 139 that is configured to transfer data, commands, and/or queries to the controller 126 over a bus 125, as described above.

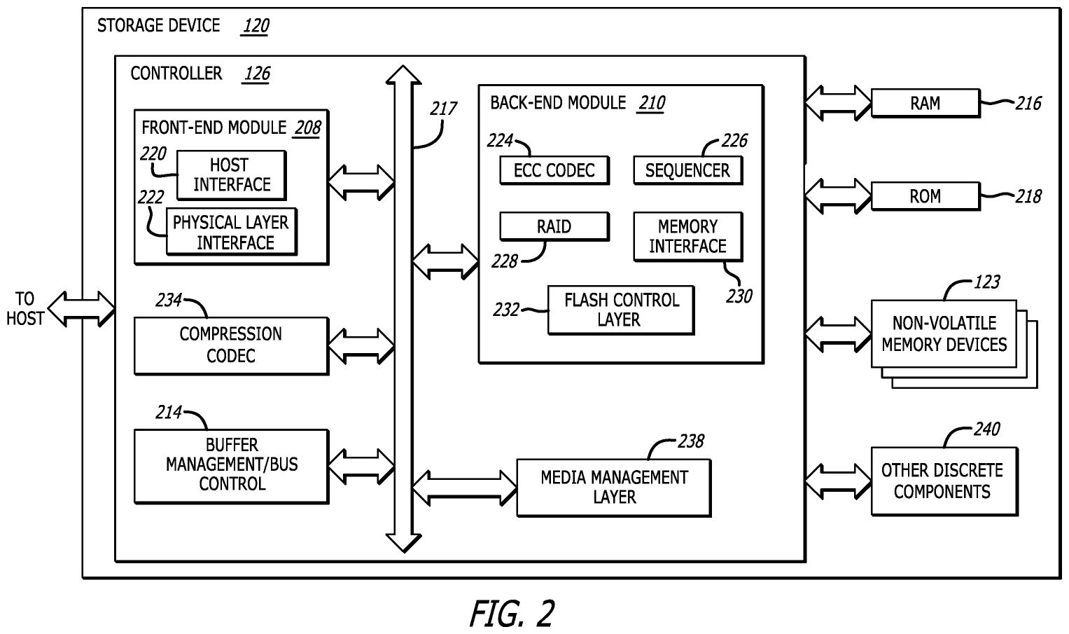

Referring to FIG. 2, a schematic block diagram of a storage device 120 suitable for utilizing internal compression codecs 234 in accordance with an embodiment of the disclosure is shown. The controller 126 may include a front-end module 208 that interfaces with a host via a plurality of high priority and low priority communication channels, a back-end module 210 that interfaces with the non-volatile memory devices 123, and various other modules that perform various functions of the storage device 120. In some examples, each module may just be the portion of the memory that comprises instructions executable with the processor to implement the features of the corresponding module without the module including any other hardware. Because each module includes at least some hardware even when the included hardware comprises software, each module may be interchangeably referred to as a hardware module.

The controller 126 may include a buffer management/bus control module 214 that manages buffers in random access memory (RAM) 216 and controls the internal bus arbitration for communication on an internal communications bus 217 of the controller 126. A read only memory (ROM) 218 may store and/or access system boot code. Although illustrated in FIG. 2 as located separately from the controller 126, in other embodiments one or both of the RAM 216 and the ROM 218 may be located within the controller 126. In yet other embodiments, portions of RAM 216 and ROM 218 may be located both partially within the controller 126 and partially outside the controller 126. Further, in some implementations, the controller 126, the RAM 216, and the ROM 218 may be located on separate semiconductor dies. As discussed below, in one implementation, the submission queues and the completion queues may be stored in a controller memory buffer, which may be housed in RAM 216.

Additionally, the front-end module 208 may include a host interface 220 and a physical layer interface 222 that provides the electrical interface with the host or next level storage controller. The choice of the type of the host interface 220 can depend on the type of memory being used. Example types of the host interfaces 220 may include, but are not limited to, SATA, SATA Express, SAS, Fibre Channel, USB, PCIe, and NVMe. The host interface 220 may typically facilitate transfer of data, control signals, and timing signals.

In a variety of embodiments, the back-end module 210 may include an error correction controller (ECC) codec 224 that encodes the data bytes received from the host and decodes and error corrects the data bytes read from the non-volatile memory devices 123. The back-end module 210 may also include a command sequencer 226 that generates command sequences, such as program, read, and erase command sequences, to be transmitted to the non-volatile memory devices 123. Additionally, the back-end module 210 may also include a RAID (Redundant Array of Independent Drives) module 228 that manages generation of RAID parity and recovery of failed data. The RAID parity may be used as an additional level of integrity protection for the data being written into the storage device 120. In some cases, the RAID module 228 may be a part of the ECC codec 224. A memory interface 230 provides the command sequences to the non-volatile memory devices 123 and receives status information from the non-volatile memory devices 123. Along with the command sequences and status information, data to be programmed into and read from the non-volatile memory devices 123 may be communicated through the memory interface 230. A flash control layer 232 may control the overall operation of back-end module 210.

Additional modules of the storage device 120 illustrated in FIG. 2 may include a media management layer 238, which performs wear leveling of memory cells of the non-volatile memory devices 123. The storage device 120 may also include other discrete components 240, such as external electrical interfaces, external RAM, resistors, capacitors, or other components that may interface with controller 126. In alternative embodiments, one or more of the RAID modules 228, media management layer 238 and buffer management/bus control 214 are optional components that may not be necessary in the controller 126.

Finally, the controller 126 may also comprise a compression codec 234. In many embodiments, the compression codec 234 can be configured to receive, instruct, and/or otherwise process data entering or leaving the storage device 120 such that all data stored within the non-volatile memory devices 123 are compressed and all compressed data retrieved and sent back to the host is decompressed. As discussed in more detail below, the compression codec 234 can utilize a variety of encoding methods to minimize the actual bits needed to be stored on the non-volatile memory devices 123 which can extend their useful operational lifespans and increase the overall amount of storage available. In certain embodiments, the compression codec 234 may be utilized by the controller 126 to respond to a low available storage space warning and work to automatically compress or recompress the data stored within the non-volatile memory devices 123.

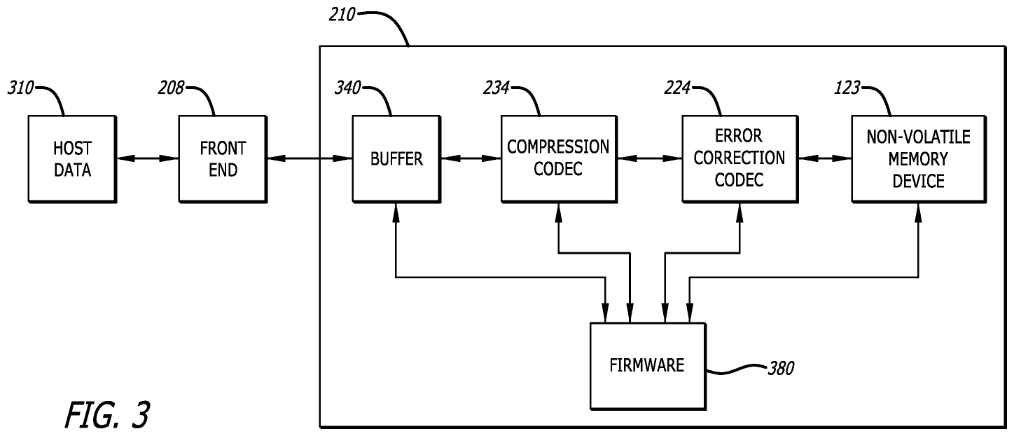

Referring to FIG. 3, a conceptual illustration of a storage device back-end module 210 utilizing an internal compression codec 234 in accordance with an embodiment of the disclosure is shown. By way of illustrating a more direct signal path, the embodiment depicted in FIG. 3 shows the compression and decompression signal chain that may be utilized. The storage device comprises a front-end module 208 that can directly communicate with the host computing device. The front-end module 208 may receive or transfer host data 310 from the host computing device to one or more buffers 340 which, as described above, may exist in the RAM of the storage device.

The host data 310 may be intended by the host computing device to be stored on one or more non-volatile memory devices 123. However, in order to reduce the data stored within the storage device, the compression codec may process the data within the buffer 340 by compressing it via one or more compression processes. As discussed below, the compression processes may include various methods such as, but not limited to, fixed-bit length encoding, and/or run-length encoding. In further embodiments, the compression codec 234 may “cascade” or recompress the compressed data to achieve even greater data space savings. It will be recognized by those skilled in the art that such recompressions may incur additional processing time requirements that may not be suitable or desirable in various applications. As discussed in more detail below, the process of compressing and recompressing the received and/or stored host may utilize one or more hardware-based computing resources in response to a particular time-based threshold being exceeded.

In many embodiments, prior to storage, the compressed and/or recompressed data can be processed through one or more ECC codec(s) 224. Often, the process of generating and verifying compressed and/or recompressed data is similar to the process of generating and verifying uncompressed data. In this way, no modifications may need to be done to existing ECC codecs 224 to facilitate integrations with a compression codec 234. For example, the ECC codec 224 may append parity bits to the compressed and/or recompressed data prior to storage.

Once processed, the compressed and error corrected data may be stored in one or more non-volatile memory devices 123. Upon request, the stored data may be retrieved from the non-volatile memory devices 123 can be directed back to the host computing device. The stored data can be verified for accuracy by the ECC codec 224 and then uncompressed by the compression codec 234 prior to being transferred back to the buffer 340. The front-end module 208 may then transfer the data stored in the buffer 340 back to the host computing device as host data 310. In this way, the host computing device may be unaware, or “blind,” to the internal compression and decompression processes. In other words, the host computing device may operate normally and without special instructions, hardware, or software to benefit from the internal compression achieved within the storage device.

In many embodiments, the firmware 380 operating within the storage device, which may include specialized firmware to operate the back-end module 210 may communicate and facilitate operations between all points within this data transfer from host computing device, non-volatile memory devices, and back again. In further embodiments, the firmware 380 may utilize one or more machine-learning based processes to identify one or more usage patterns between the storage device and host-computing device. The identified usage patterns can be utilized within the storage device to apply or otherwise change the levels of compression used. For example, storage device usage at a preconfigured, routine time may be considered high-priority and therefore requires a lower level of compression in order to facilitate speedy writing of the data to the memory device. The one or more machine-learning processes may utilize a variety of data inputs to generate usage patterns within the storage device. The limit of the machine-learning operations can be related to the available computing resources and/or input data points.

As those skilled in the art will recognize, the particular structure of the storage device and the constituent components necessary to facilitate internal compression as described herein may be different than as depicted in FIG. 3. Indeed, embodiments may be realized where the compression codec 234 is separated as a compression encoder and compression decoder, each with particular hardware and/or software computing resources available. Additionally, components depicted herein may be situated in various arrangements beyond the specific embodiment depicted in FIG. 3. For example, and component may operate outside of the back-end module 210 and may be processed externally from the storage device.

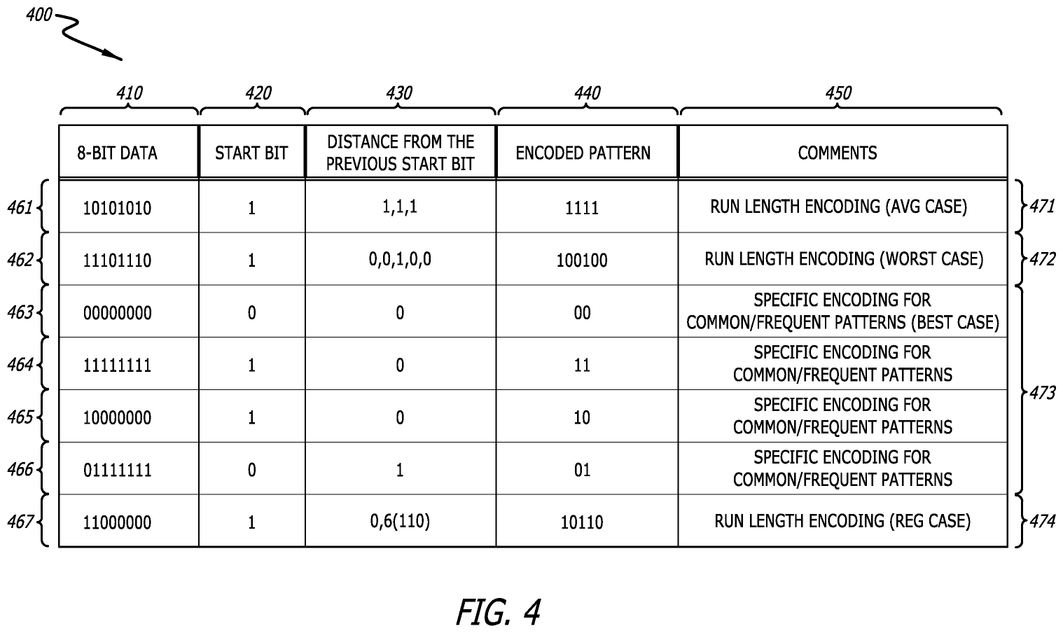

Referring to FIG. 4, a table 400 depicting a sample of compression encodings 461-467 in accordance with embodiments of the disclosure is shown. Although not provided as limiting material, the specific compression encodings 461-467 depicted herein are provided for illustration purposes to highlight the potential space savings that may occur in many embodiments. The table 400 comprises a plurality of 8-bit data (bytes) 410 which may be submitted for compression. The output of the compression process is shown as encoded patterns 440 which may vary in length depending on the success of the compression process. Comments 450 regarding each specific compression encoding 461-467 are also displayed in the table 400.

In a variety of embodiments, including the embodiment depicted in FIG. 4, the compression process may begin by examining the start bit 420 which can be either a zero or one. The compression process may subsequently determine a distance between the start bit and the next similar bit value. This can be seen in the distance from the previous start bit column 430. For example, the first compression encoding 461 receives an alternating pattern of ‘10’ within the byte 10101010. The compression process may locate the start bit of ‘1,’ and then find the next similar starting bit after one non-starting bit value. This repeats until the last starting bit value is recorded and the final encoded pattern is ‘1111’. We can recognize from this processing, that a different but similar 01010101 byte would yield an encoded pattern of ‘0111’.

Similar encodings can be seen in the second compression encoding 462 and last compression encoding 467. The second compression encoding receives a byte of 11101110 which has a starting bit of 1 and has zero distance between it and the next bit in the byte with the same starting value of 1. The third bit is also the same value of the starting bit. Next, there is only one space before another bit with the starting bit value is found, followed by another two bits with the starting value prior to ending. The encoded pattern output is thus 100100 which yields a twenty-five percent storage savings, while being categorized within the worst-case scenario cases 472. Likewise, the last compression encoding 467 has a starting bit of ‘1’ and is followed directly by another bit with the value of ‘1’ before having six non-starting value bits within the byte. In this last compression encoding 467, the distance between starting bits can be marked as ‘0’ and ‘6’ (to indicate six spaces at the end of the byte and to avoid conflicting with specialized input patterns discussed below. The ‘6’ value can be represented in binary as 110 which yields an encoded pattern of 10110 to indicate the starting bit, distance to the next starting bit, and remaining spaces within the 8-bit data.

There are specialized cases where common or otherwise frequent input data patterns may be optimized by using one or more specific encodings 473. For example, the third compression encoding 463 may be for a byte that comprises only bits with a value of ‘0’. Utilizing the methods described above, the resulting encoded pattern could be superimposed to yield 11111111. However, this would limit storage settings so a specialized case may be utilized that directly compresses the 8-bit data to a 2-bit encoded pattern of ‘00’.

Likewise, the fourth compression encoding 464 input pattern of 11111111 may be compressed to an encoded pattern of ‘11’. The final special cases are inverses of a pattern of a first starting bit and all remaining bits are of a different value. For these cases, the final encoded pattern can be two bits comprising the starting bit followed by the opposite bit value. Thus, the fifth compression encoding 465 shows the input 8-bit data byte of 10000000 being compressed to the encoded pattern of 10 and the sixth compression encoding 466 of 01111111 yields an encoded pattern of ‘01’.

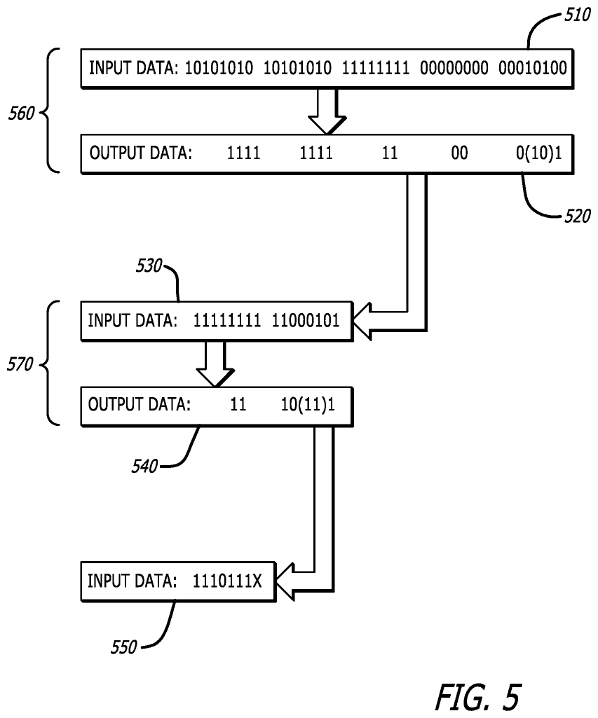

As those skilled in the art will appreciate, this compression process can be preconfigured into a hardware and/or software module that may be deployed on one or more storage devices. The methods of compression utilized may be swapped and/or otherwise switched between or during usage. As depicted in FIG. 4, a specialized combination of preconfigured encoded patterns may be utilized that vary from a run length encoding method 461, 462, 467 which can vary from regular cases 474 to worst cases 472, with a potential average case 471 which can save fifty percent of storage space. With the combination compression processes outlined herein, a storage savings of twenty-five to eighty percent can be achieved on the first level of compression. Additional cascades or recompressions are discussed in more detail within FIG. 5.

Referring to FIG. 5, a conceptual illustration of a cascading compression process in accordance with an embodiment of the disclosure is shown. As discussed above, the compression processes utilized within an internal compression codec may allow for the recompressing of data to achieve even greater storage space savings. In many embodiments, the compression method utilized may require a fixed input, typically a particular number of bytes. As described above, the compression methods may be configured to best compress data when a limited number of cases are processed and accounted for. For example, a variety of embodiments may require all incoming data for compression to be processed as 8-bit increments (bytes). In further embodiments, the compression codec may continue to recompress data until the minimum fixed-input size is not available.

An example of the recompression process and associated limits of this respective embodiment are shown in FIG. 5. The compression codec has a block of five 8-bit data bytes provided as input data 510 for compression. Utilizing similar compression processes as those depicted in FIG. 4, the output data 520 may reduce the input data size from 40 bits to 16 bits. This first level of compression 560 may be directed back into the compression codec (or in additional embodiments, a second or specialized recompression codec with differing processes) as recompression input data 530 within a second level of compression 570. The 16 compressed data bits are then compressed into output data 540 comprising 7 data bits. This (and any) output data 540 may be concatenated and presented as input data 550 again. However, the compression and/or recompression codec would determine that recompression is unavailable as the input data is less than the required fixed input.

A benefit of utilizing a fixed-input compression method is that the all data is processed equally. Practically, this allows for the use of internal compression codecs on any type of operating system or specially formatted data. Thus, storage devices may be equipped with a single or otherwise universal internal compression codec that can be deployed in any potential environment. This further allows for the use of this technology on host computing devices without requiring changes, updates, or other installation of specialized software in most embodiments.

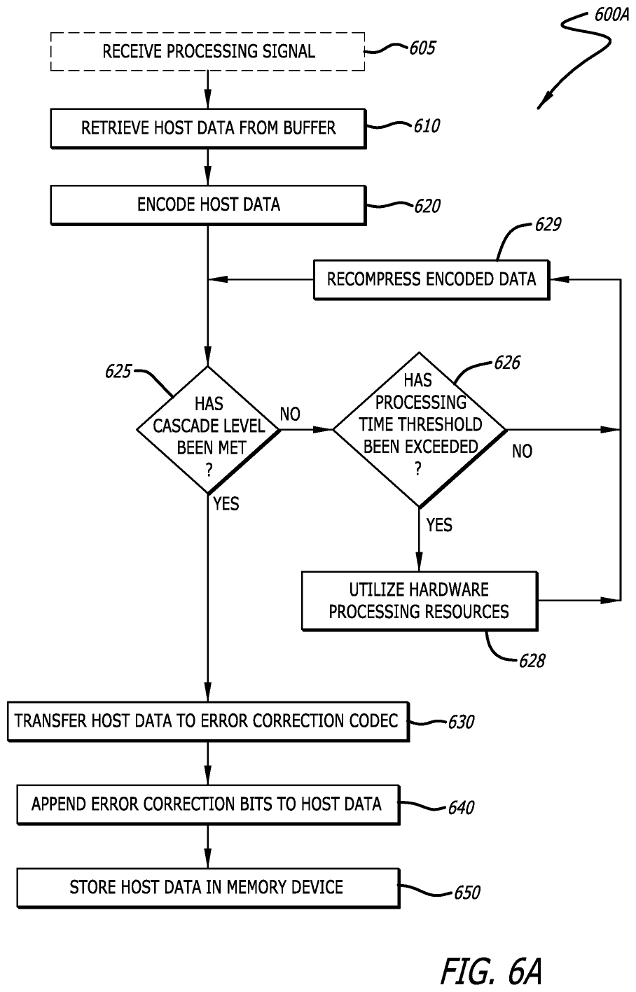

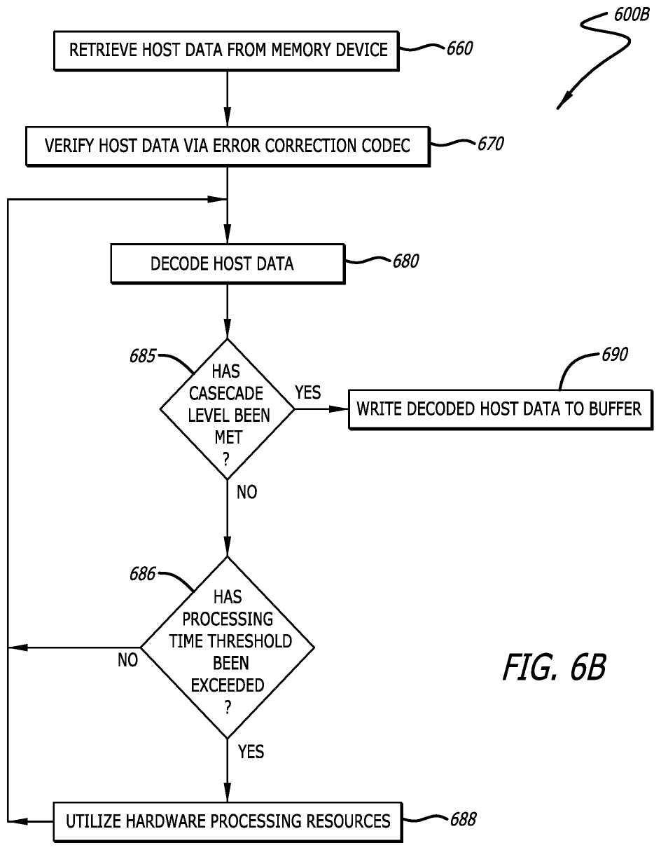

Referring to FIG. 6A a flowchart depicting a process 600A for utilizing internal compression when storing data to a plurality of memory devices in accordance with embodiments of the disclosure is shown. In some embodiments, the process 600A may begin by receiving a processing signal (block 605). This processing signal may be external to the storage device or may be internal in response to a specific state or threshold being triggered. In many embodiments, the firmware will monitor one or more buffers for incoming host data to process. Once deposited into one of those buffers, the process 600A can retrieve the host data from a buffer and direct it towards the compression codec (block 610). Upon receipt, the compression codec can encode the host data utilizing one of the compression methods preconfigured either within the firmware or the compression codec itself (block 620). As described above, the host data may be presented to the compression codec in fixed input data lengths such as, but not limited to, 8-bits.

In certain embodiments, the compression codec may be configured for, or may be signaled to recompress the host data after compression through one or more “cascade” levels. The process 600A may determine after initial encoding whether the appropriate cascade level has been met (block 625). If recompression is needed, the process 600A may then further determine if one or more processing time thresholds have been exceeded (block 626). Time-based thresholds may be configured to reduce the overall latency of compression time needed to store the host data within the storage device. These thresholds may also be dynamically generated based on factor such as the current state of the buffer. Thus, when additional data is ready to be compressed, the time-based threshold may be dynamically changed (e.g., reduced).

When the time-based threshold has been exceeded, the process 600A can utilize or call on hardware processing resources to reduce the time needed for recompression (block 628). As those skilled in the art will understand, the process 600A may also utilize additional software computing resources in various embodiments, especially when multiple compression codecs are comprised within a single storage device. Once utilized, recompression of the data may occur (block 629). Similarly, when time-based thresholds are not exceeded, the recompression of data may occur as well (block 629).

Once the cascade level has been met, the compressed/recompressed host data can be transferred to the error correction codec (block 630). In some embodiments, the process 600A may not utilize an error correction codec. Once received, the error correction codec may append one or more error correction (i.e., “parity”) bits to the compressed/recompressed host data (block 640). In certain embodiments, the error correction codec may process the host data in different ways beyond appending bits. Once the compressed/recompressed host data has been processed for error correction, the resulting data may then be stored within one or more memory device(s) (block 650).

Referring to FIG. 6B, a flowchart depicting a process 600B for utilizing internal compression when retrieving data from a plurality of memory devices in accordance with embodiments of the disclosure is shown. As a mirror to the process 600A depicted in FIG. 6A, the process 600B begins the process of returning stored host data by retrieve the compressed/recompressed host data from the one or more memory devices (block 660). The error correction codec can subsequently process the retrieved data to verify the data (block 670). The resulting error-corrected compressed/recompressed data is passed to the compression codec which may then decode the host data (block 680).

Similarly to the process 600A, the data to process may have been recompressed one or more times. The process 600B checks if the cascade level has been met for the received data (block 685). When the decoded data requires more decoding, it can further be determined if one or more processing time-based thresholds have been exceeded (block 686). The time-based thresholds associated with the decoding process may be similar to the encoding process but may be pre-configured to reflect desired processing and data retrieval times that have been advertised to storage device consumers. Furthermore, dynamically based thresholds may be generated in response to other external signals such as, but not limited to, additional requests for data from the host, and/or received priority indications.

When time-based thresholds have not been exceeded, the process 600B may process the host data for further decoding (block 680). Conversely, when the time-based thresholds have been exceeded, additional hardware processing resources may be utilized prior to further decoding (block 688). As with FIG. 6A, certain embodiments may utilize software-based processing resources in response to complying with one or more time-based thresholds. When the host data has been decoded to the proper cascade level, the uncompressed, original host data can be written to one or more buffers which can then pass the data back to the host (block 690).

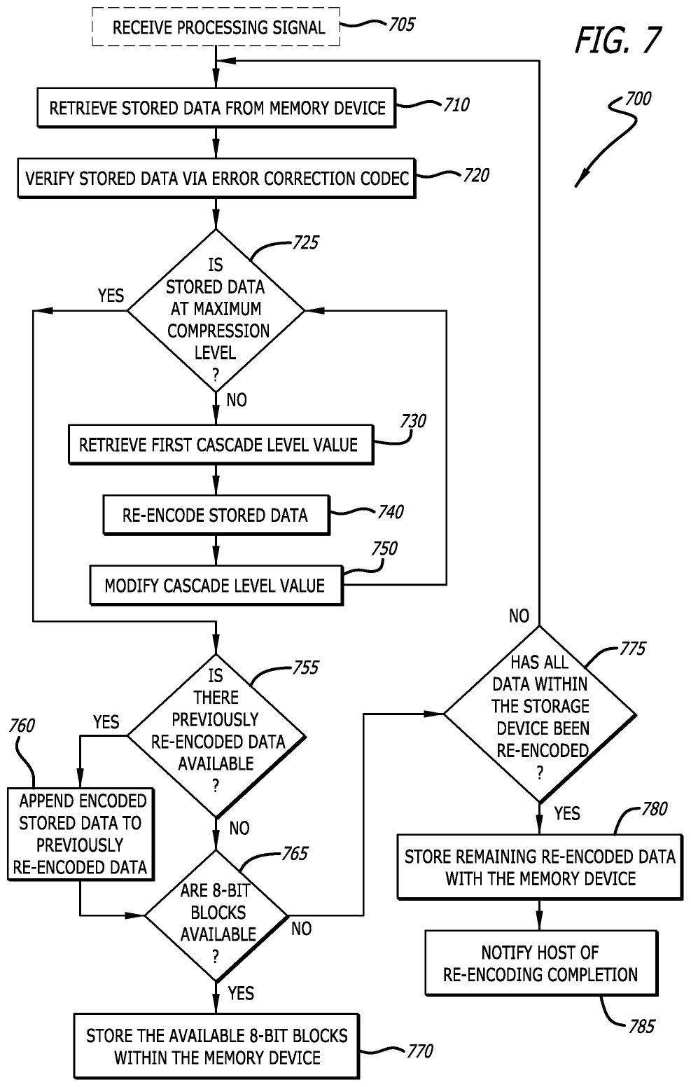

Referring to FIG. 7, a flowchart depicting a process 700 for generating additional storage space within a storage device utilizing one or more cascading compression processes in accordance with embodiments of the disclosure is shown. In a variety of embodiments, a storage device may reach storage capacity or exceed a storage capacity that triggers a warning to the host system or internal firmware/controller that storage space has almost run out. In response to receiving one or more processing signal such as these, the process 700 can begin to recompress some or all data within the storage device to create additional storage capacity (block 705). In many embodiments, this process 700 is accomplished without intervention or engagement by the host (with the exception of writing data to the memory devices that triggers the low/no capacity warning signal).

The process 700 can begin by retrieving a portion of stored data from one or more memory devices (block 710). In some embodiments, the retrieved data may be in fixed-length increments. In further embodiments, the retrieved data may be equal to or approximately the size of one or more available buffers within the storage device. The retrieved data can be processed and verified through an error correction codec prior to recompression (block 720).

Not all retrieved data will be available to recompress. For example, data may have already been compressed to a maximum available cascade level. Therefore, the process 700 can check if the stored data is at the maximum compression level (block 725). When data is determined to be at the maximum compression level, the process 700 may check to see if there is any previously re-encoded (i.e., recompressed) data within a buffer before processing more (block 755).

When further recompression of the retrieved data is possible, the process 700 can attempt to retrieve the first cascade level value (block 730). In a number of embodiments, the firmware and/or controller will have a mapping of what data within the memory devices is compressed and to what level. In additional embodiments, the formatting of the encoded data may comprise indications or bits that represent the level of compression achieved on the fixed block of data. The stored data may be re-encoded which reduces the size of the required data for storage (block 740).

Once recompressed modification of the cascade level value may occur (block 750). This may involve transmitting a signal to the firmware and/or controller to change the stored compression (i.e., cascade) level value associated with that portion of stored data. In still further embodiments, the cascade level value may be modified on the data itself. Upon modification, the process 700 can then re-check if the compressed/recompressed data is at the maximum compression level (block 725).

Once the portion of data has been recompressed to the maximum available level, the process 700 may examine if there is any previously re-encoded data available within one or more buffers (block 755). As data sizes are reduced, the reduced data chunks may need to be appended or otherwise concatenated to sequentially write the data back to the storage device efficiently (block 760). Once the old and new data has been appended or otherwise combined or if there is no previously re-encoded data available in the buffer, the process 700 can examine if any 8-bit block are available (block 765). Although the process 700 depicted in FIG. 7 determines if 8-bit blocks are available, the process 700 may examine if any blocks of a fixed length corresponding to the compression codec input.

When 8-bit blocks of data are available, the process 700 can store the blocks within one or more memory devices (block 770). If the remaining data (of less than 8 bits in size) remains in the buffer either prior or after the storage of the 8-bit blocks, the process 700 may further determine if all data within the storage device has been re-encoded (block 775). When more data is available within the memory array to process, the data may be retrieved and further processed (block 710). When all of the data within the storage device has been re-encoded, the remaining re-encoded data can be stored within the one or more memory devices (block 780). Upon completion of all storage tasks, the host may be notified of completion of the re-encoding process 700 (block 785). However, in some embodiments, the host may not be notified of the process 700 and may be notified of the increased storage space in response to sending a general query to the storage device. This process 700 may be a passive process in regard to the host and may be utilized based solely on internal commands and processes.

It should be understood by those skilled in the art that the embodiment depicted in FIG. 7 is illustrative and may be implemented in a variety of ways and in a variety of orders. For example, the process 700 may be configured to simply attempt to recompress the stored host data a single time instead of attempting to reach the maximum compression level with each piece of stored data. Similarly, the entire storage device and associated memory array may be subject to this process. For example, one or more virtual drives may be partitioned within the storage device that yields a local low-storage warning as opposed to a global low-storage warning within the entire storage device as depicted in FIG. 7.

Information as herein shown and described in detail is fully capable of attaining the above-described object of the present disclosure, the presently preferred embodiment of the present disclosure, and is, thus, representative of the subject matter that is broadly contemplated by the present disclosure. The scope of the present disclosure fully encompasses other embodiments that might become obvious to those skilled in the art, and is to be limited, accordingly, by nothing other than the appended claims. Any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each and every problem sought to be resolved by the present disclosure, for solutions to such problems to be encompassed by the present claims. Furthermore, no element, component, or method step in the present disclosure is intended to be dedicated to the public regardless of whether the element, component, or method step is explicitly recited in the claims. Various changes and modifications in form, material, work-piece, and fabrication material detail can be made, without departing from the spirit and scope of the present disclosure, as set forth in the appended claims, as might be apparent to those of ordinary skill in the art, are also encompassed by the present disclosure.

What is claimed is:

1. A storage device comprising:
one or more communication channels suitable for connection with a host-computing device;
a plurality of memory devices within a memory array;
a plurality of controllers configured to transfer host data from the host-computing device to the memory array, wherein at least one of the plurality of controllers further includes a compression codec configured to:
retrieve host data from one or more buffers;
compress the host data with a fixed-input compression method; and
store the compressed host data within one or more memory devices.

2. The storage device of claim 1, wherein all data stored within the memory array is compressed via the fixed-input compression method.

3. The storage device of claim 1, wherein the fixed input is eight bits.

4. The storage device of claim 1, wherein the fixed-input compression method utilizes run-length encoding.

5. The storage device of claim 1, wherein the fixed-input compression method utilizes fixed-bit encoding.

6. The storage device of claim 1, wherein the fixed-input compression method utilizes both run-length and fixed-bit encoding.

7. The storage device of claim 6, wherein the determination of either run-length or fixed-bit encoding is based on the composition of the retrieved host data.

8. The storage device of claim 1, wherein the compression codec is further configured to recompress the compressed host data with a similar fixed-input compression method.

9. The storage device of claim 8, wherein the recompression of the compressed data is limited to compressed data that is equal to or greater in size of the fixed-input size.

10. The storage device of claim 8, wherein the determination of recompressing of compressed host data is based on the expected processing time to recompress the compressed data.

11. The storage device of claim 1, wherein the compression of the host data yields between twenty-five percent and eighty percent reduction in size.

12. The storage device of claim 1, wherein the compression codec is further configured to:
receive a request for stored data retrieval;
retrieve the requested compressed data from one or more memory devices;
decompress the compressed data; and
transfer the decompressed data to one or more buffers;

13. The storage device of claim 1, wherein the compression codec is further configured to encode compressed host data with one or more error correction parity bits provided by an error correction codec prior to storage within the one or more memory devices.

14. The storage device of claim 1, wherein the compression codec may utilize one or more hardware-based processing resources in response to a time-based threshold being exceeded.

15. The storage device of claim 1, wherein the stored compressed data is comprised of data generated from multiple operating systems.

16. The storage device of claim 1, wherein the compression codec may have one or more inputs suitable for machine-based training to dynamically adjust the desired level of compression.

17. The storage device of claim 16, wherein the one or more inputs can be configured to provide data associated with input and output data patterns of the storage device.

18. A method of compressing host data within a storage device comprising:
receiving a desired level of compression;
retrieving host data from one or more buffers;
encoding the host data with a fixed-input compression algorithm;
verifying if the desired level of compression threshold has been achieved wherein, in response to the compression threshold not being achieved, re-encoding the host data with the fixed-input compression algorithm until the compression threshold has been achieved; and
appending error correction data to the compressed host data;
storing the compressed host data within one or more memory devices.

19. The method of claim 18, wherein the method further:
retrieves, in response to a received request, the stored host data from the one or more memory devices;
verifies the data via the appended error correction data;
decodes the compressed host data; and
transfers the decoded host data to one or more buffers.

20. A storage device comprising:
one or more communication channels suitable for connection with a host-computing device;
a plurality of memory devices within a memory array;
a plurality of controllers configured to transfer host data from the host-computing device to the memory array,
a fixed-input compression codec communicatively coupled with plurality of controllers,
wherein in response to receiving a signal associated with low storage device capacity, the storage device:
retrieves compressed data from one or more memory devices;
determines if the compressed data is suitable for recompression and upon determination of suitability, recompresses the compressed data via the fixed-input compression codec;
stores the recompressed data within one or more memory devices within the memory array.
